(19) United States
(12) Patent Application Publication
(10) Pub. No.: US 2017/0117464 A1
(43) Pub. Date: Apr. 27, 2017

(54) RESISTIVE RANDOM ACCESS MEMORY DEVICE

(71) Applicant: Winbond Electronics Corp., Taichung City (TW)

(72) Inventors: Frederick CHEN, Zhubei City (TW); Shao-Ching LIAO, Tongluo Township (TW); Ping-Kun WANG, Taichung City (TW)

(21) Appl. No.: 14/920,656

(22) Filed: Oct. 22, 2015

(51) Int. Cl. H01L 45/00

(52) U.S. Cl. CPC H01L 45/08; H01L 45/1233; H01L 45/1253; H01L 45/1246; H01L 45/146

(57) ABSTRACT

A resistive random access memory device is provided, which includes a bottom electrode, a resistive switching layer disposed on the bottom electrode, an oxidizable layer disposed on the resistive switching layer, a first oxygen diffusion barrier layer disposed between the oxidizable layer and the resistive switching layer, and a second oxygen diffusion barrier layer disposed on the oxidizable layer.

### BACKGROUND

Technical Field

The disclosure relates to a resistive random access memory (RRAM) device, and in particular it relates to a stack structure of the RRAM device.

Description of the Related Art

The resistive random access memory (RRAM) device has become a major stream of the newly developed non-volatile memory due to the following advantages: low power consumption, low operation voltage, short write and erase times, long endurance, long data retention time, non-destructive read operation, multi-state memory, simple manufacture, and scalable properties. The basic structure of the RRAM device includes a metal-insulator-metal (MIM) stack of a bottom electrode, a resistive switching layer, and a top electrode. The resistive switching (RS) property is an important property of the RRAM device. For example, when a writing voltage (turn-on voltage) is applied to the RRAM device, the oxygen atoms in the resistive switching layer may migrate to the top electrode to achieve the RS effect. However, the oxygen atoms may diffuse back to the resistive switching layer or even escape out of the top electrode to render the RRAM device ineffective.

Accordingly, a novel RRAM device and method for manufacturing the same for overcoming the above shortcomings are called-for.

### BRIEF SUMMARY

One embodiment of the disclosure provides a resistive random access memory device, including: a bottom electrode; a resistive switching layer disposed on the bottom electrode; an oxidizable layer disposed on the resistive switching layer; a first oxygen diffusion barrier layer disposed between the oxidizable layer and the resistive switching layer; and a second oxygen diffusion barrier layer disposed on the oxidizable layer.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows a cross-sectional view of a RRAM device in one embodiment of the disclosure.

FIG. 2 shows a cross-sectional view of a RRAM device in another embodiment of the disclosure.

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

In one embodiment, a non-volatile memory such as a resistive random access memory (RRAM) device is provided. In a conventional RRAM device, the oxygen in the top electrode (migrating from a resistive switching layer by applying a voltage to the RRAM device) may diffuse back (down-toward) to the resistive switching layer, or escape out (upward) of the top electrode. The above oxygen diffusion and escape may cause the RRAM device to be ineffective. A novel RRAM stack structure is provide here to overcome the above oxygen diffusion/escape problem.

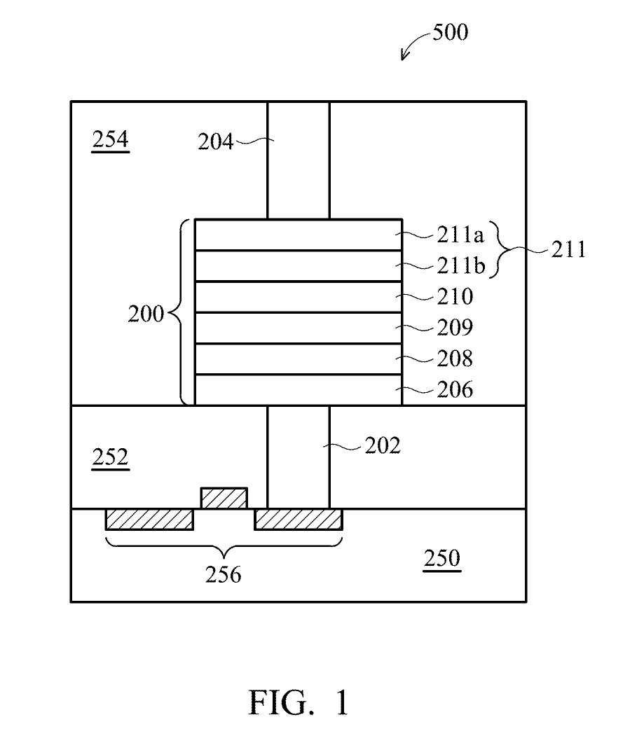

FIG. 1 shows a cross-sectional view of a RRAM device 500 in one embodiment. As shown in FIG. 1, the RRAM device 500 can be disposed on a semiconductor substrate 250. In one embodiment, the semiconductor substrate 250 can be a silicon substrate. The RRAM device 500 mainly includes following elements: a bottom electrode contact plug 202 disposed on the semiconductor substrate 250, a bottom electrode 206 disposed on and contacting the bottom electrode contact plug 202, a resistive switching layer 208 disposed on the bottom electrode, a first oxygen diffusion barrier layer 209 disposed on the resistive switching layer 208, an oxidizable layer 210 disposed on the first oxygen diffusion barrier layer 209, a second oxygen diffusion barrier layer 211 disposed on the oxidizable layer 210, and a top electrode contact plug 204 disposed on and contacting the second oxygen diffusion barrier layer 211.

In one embodiment, the bottom electrode contact plug 202 and the top electrode contact plug 204 can be composed of tungsten (W). In one embodiment, the bottom electrode 206 can be composed of tungsten (W), platinum (Pt), aluminum (Al), titanium (Ti), titanium nitride (TiN), or a combination thereof with a thickness of 10 to 100 nm. An overly thin bottom electrode 206 may lead to excessive sensitivity to underlying roughness. An overly thick bottom electrode 206 may suffer from crystallization-related microstructural changes. In one embodiment, the oxidizable layer 210 can be composed of titanium with a thickness of 10 nm to 50 nm. An overly thin oxidizable layer 210 may receive oxygen from the resistive switching layer 208 and become oxidized, preventing low voltage operation. An overly thick oxidizable layer 210 may receive too much oxygen from the resistive switching layer 208, causing it to lose switching ability. In one embodiment, the bottom electrode 206 and the oxidizable layer 210 can be formed by E-beam evaporation, sputtering, or physical vapor deposition (PVD).

In one embodiment, the resistive switching layer 208 can be composed of hafnium oxide, titanium oxide, tungsten oxide, tantalum oxide, zirconium oxide, or a combination thereof with a thickness of 5 nm to 10 nm. An overly thin resistive switching layer 208 may leak too much current and not switch. An overly thick resistive switching layer 208 may be too difficult to form into a resistive switching element. In one embodiment, the resistive switching layer 208 can be formed by atomic layer deposition (ALD).

In one embodiment, the first oxygen diffusion barrier layer 209 (disposed between the resistive switching layer 208 and the oxidizable layer 210) can be composed of aluminum oxide with a thickness of 0.3 nm to 0.6 nm. An overly thin first oxygen diffusion barrier layer 209 cannot efficiently prevent the oxygen in the oxidizable layer 210 (migrating from the resistive switching layer 208) from diffusing back to the resistive switching layer 208 while no voltage being applied to the RRAM device. An overly thick first oxygen diffusion barrier layer 209 may largely increase the total resistance of a MIM structure 200 and the driving voltage of the RRAM device, or even make the RRAM device be ineffective. In one embodiment, the first oxygen diffusion barrier layer 209 can be formed by ALD.

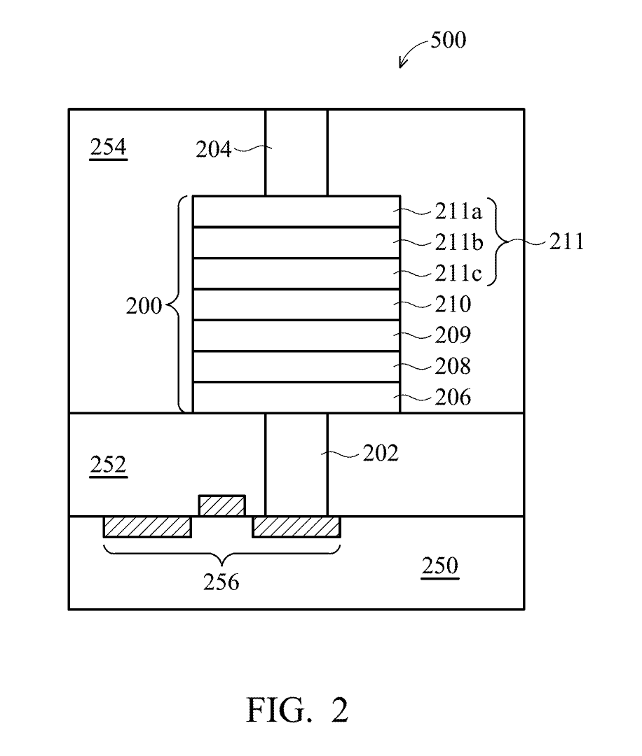

In one embodiment, the second oxygen diffusion barrier layer 211 (disposed between the oxidizable layer 210 and the top electrode contact plug 204) is a bi-layered structure comprising a titanium oxynitride layer 211b disposed under a titanium nitride layer 211a, as shown in FIG. 1. In this embodiment, the titanium oxynitride layer 211b has a thickness of 5 nm to 15 nm, and the titanium nitride layer 211a has a thickness of 1.0 nm to 20 nm. An overly thin titanium oxynitride layer cannot efficiently prevent the oxygen in the oxidizable layer 210 (migrating from the resistive switching layer 208) from escaping out (upward) of the oxidizable layer 210 while no voltage being applied to the RRAM device. An overly thick titanium oxynitride layer may largely increase the total resistance of a MIM structure 200 and the driving voltage of the RRAM device, or even make the RRAM device be ineffective. In another embodiment, an additional titanium nitride layer 211c is disposed under the titanium oxynitride layer 211b, as shown in FIG. 2. An overly thick titanium nitride layer under the oxynitride layer may put the oxynitride layer too far away to prevent oxygen from moving too far from the oxidizable layer 210, and make the fabrication more difficult (thicker layer to etch). In one embodiment, the titanium nitride layer on the titanium oxynitride layer and the titanium nitride layer under the titanium oxynitride layer have a similar thickness. In one embodiment, the titanium, oxygen, and nitrogen of the titanium oxynitride layer have a molar ratio of 4:0.04:1 to 4:1:3. An overly low oxygen ratio cannot prevent the oxygen escape problem. An overly high oxygen ratio will largely increase the total resistance of a MIM structure 200 and the driving voltage of the RRAM device, or even cause the RRAM device to be ineffective. In one embodiment, the titanium nitride layers and the titanium oxynitride layer can be formed by E-beam evaporation, sputtering, PVD, or ALD. In this embodiment, the top TiN layer 211a of the second oxygen diffusion barrier layer 211 may serve as the top electrode of the MIM structure 200.

Alternatively, the second oxygen barrier layer 211 is a bi-layered structure of an aluminum oxide layer 211b disposed under the titanium nitride layer 211a, as shown in FIG. 1. In this embodiment, the aluminum oxide layer has a thickness of 0.3 nm to 0.6 nm, and each of the titanium nitride layers has a thickness of 10 nm to 20 nm. An overly thin aluminum oxide layer cannot efficiently prevent the oxygen in the oxidizable layer 210 (migrating from the resistive switching layer 208) from escaping upward and out of the oxidizable layer 210 while no voltage being applied to the RRAM device. An overly thick aluminum oxide layer may largely increase the total resistance of a MIM structure 200 and the driving voltage of the RRAM device, or even make the RRAM device be ineffective. In one embodiment, the titanium nitride layer can be formed by E-beam evaporation, sputtering, or PVD, and the aluminum oxide layer can be formed by PVD or ALD. In this embodiment, the top TiN layer 211a of the second oxygen diffusion barrier layer 211 may serve as the top electrode of the MIM structure 200.

The above bottom electrode 206, the resistive switching layer 208, the first oxygen diffusion barrier layer 209, the oxidizable layer 210, and the second oxygen diffusion barrier layer 211 construct the MIM structure 200.

The RRAM device 500 can be operated as below. A positive (negative) bias voltage is applied to the RRAM device 500 to switch its resistance state. When a top electrode contact plug 204 of the RRAM device 500 is applied by the positive (negative) bias voltage, a current through the RRAM device 500 increases as the bias voltage is increased. If a current through the RRAM device 500 increases to a current limit, the corresponding bias voltage serves as a forming voltage. The forming voltage usually has a high value. At this time, the RRAM device 500 is switched from an original state (O-state) to a low resistance state (LRS, or referred as ON-state). Next, when a turn-off voltage is applied to the top electrode contact plug 204 of the RRAM device 500, the RRAM device 500 starts to decrease the current therethrough. When the turn-off voltage reaches a limit, the current through the RRAM device 500 suddenly returns to a lower value. At this time, the RRAM device 500 is switched from the LRS to a high resistance state (HRS, or referred as OFF-state). Subsequently, a turn-on voltage is applied to the top electrode contact plug 204 of the RRAM device 500, a current through the RRAM device 500 increases as the bias voltage is increased, and the current through the RRAM device 500 increases up to a current limit. At this time, the RRAM device 500 is switched from the HRS to the LRS. The switching between the various resistance states is repeatable. In addition, a reading voltage less than the erase voltage (turn-off voltage) and the writing voltage (turn-on voltage) can be applied to the RRAM device 500 at HRS and LRS, for reading the current through the RRAM device 500 to check the memory state of the RRAM device 500. In other words, the bias voltage applied to the RRAM device 500 can be adjusted to switch the resistance state of the RRAM device 500, thereby achieving the purpose of recording data. Moreover, the LRS and HRS can be maintained without an external power, it means the RRAM 500 can be utilized as a non-volatile memory.

The manufacture of the RRAM device 500 in one embodiment is described below. First, a semiconductor substrate 250 such as silicon substrate is provided and cleaned by a wet clean process. A transistor 256 is provided on the semiconductor substrate 250. Note that the transistor 256 in the drawing is just for illustration and be not limited thereto. An ILD layer 252 can be then deposited as a blanket by chemical vapor deposition (CVD) or plasma enhanced CVD (PECVD). An opening can be then formed in the ILD layer 252 by a patterning process, e.g. lithography and anisotropic etching, thereby defining a location of the bottom electrode contact plug 202 in contact with the transistor 256 (e.g. the drain electrode of the transistor 256). A barrier layer such as titanium or titanium nitride can be then deposited on sidewalls of the opening by CVD, and the opening can be then filled with a conductive material such as tungsten. Thereafter, a planarization process such as chemical mechanical polishing (CMP) can be used to remove the excess conductive material over the top surface of the ILD layer 252, thereby forming the bottom electrode contact plug 202 in the opening. Subsequently, a bottom electrode layer can be formed on the ILD layer 252 by E-beam evaporation, sputtering, or PVD. A resistive switching layer can be then formed on the bottom electrode layer by ALD. In one embodiment, the resistive switching layer can be annealed by the rapid thermal annealing (RTA) after forming the resistive switching layer. A first oxygen diffusion barrier layer (e.g. aluminum oxide layer) can be then formed on the resistive switching layer by ALD. Subsequently, an oxidizable layer can be formed on the first oxygen diffusion barrier layer by E-beam evaporation, sputtering, PVD, or ALD. A second oxygen diffusion barrier layer can be then formed on the oxidizable layer by E-beam evaporation, sputtering, PVD, or ALD. Thereafter, the first oxygen diffusion layer, the oxidizable layer, the first oxygen diffusion layer, the resistive switching layer, and the bottom electrode layer are patterned to define the second oxygen diffusion barrier layer 211, the oxidizable layer 210, the first oxygen diffusion barrier layer 209, the resistive switching layer 208, and the bottom electrode 206, whcih construct the MIM structure 200.

Thereafter, an ILD layer 254 is deposited as a blanket by CVD or PECVD. An opening can be then formed in the ILD layer 254 by a patterning process, e.g. lithography and anisotropic etching, thereby defining a location of the top electrode contact plug 204 and exposing a part of the oxidizable layer 210. A barrier layer such as titanium or titanium nitride can be then deposited on sidewalls of the opening by CVD, and the opening can be then filled with a conductive material such as tungsten. Thereafter, a planarization process such as CMP can be used to remove the excess conductive material over the top surface of the ILD layer 254, thereby forming the top electrode contact plug 204 in the opening. It should be understood that the RRAM device 500 can be manufactured through above steps but is not limited to those steps.

While the disclosure has been described by way of example and in terms of the preferred embodiments, it is to be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

1. A resistive random access memory device, comprising:
a bottom electrode;
a resistive switching layer disposed on the bottom electrode;
an oxidizable layer of titanium disposed on the resistive switching layer;
a first oxygen diffusion barrier layer of aluminum oxide disposed between the oxidizable layer and the resistive switching layer; and
a second oxygen diffusion barrier layer disposed on the oxidizable layer,
wherein the second oxygen diffusion barrier layer comprises a titanium oxynitride layer or an aluminum oxide layer disposed under a top electrode.

2. The resistive random access memory device as claimed in claim 1, wherein the bottom electrode comprises tungsten, platinum, aluminum, titanium, titanium nitride, or a combination thereof, and the bottom electrode has a thickness of 10 to 100 nm.

3. The resistive random access memory device as claimed in claim 1, wherein the resistive switching layer comprises hafnium oxide, titanium oxide, tungsten oxide, tantalum oxide, or zirconium oxide, or mixtures thereof, and the resistive switching layer has a thickness of 5 nm to 10 nm.

4. The resistive random access memory device as claimed in claim 1, wherein the oxidizable layer has a thickness of 10 nm to 50 nm.

5. The resistive random access memory device as claimed in claim 1, wherein the first oxygen diffusion barrier layer has a thickness of 0.3 nm to 0.6 nm.

6. The resistive random access memory device as claimed in claim 1, wherein top electrode is a titanium nitride layer.

7. The resistive random access memory device as claimed in claim 1, wherein the second oxygen diffusion barrier layer further comprises another titanium nitride layer disposed under the titanium oxynitride layer.

8. The resistive random access memory device as claimed in claim 6, wherein the titanium oxynitride layer has a thickness of 5 nm to 15 nm, and the titanium nitride layer has a thickness of 10 nm to 20 nm.

9. The resistive random access memory device as claimed in claim 6, wherein the titanium, oxygen, and nitrogen of the titanium oxynitride layer have a molar ratio of 4:0.04:1 to 4:1:3.

10. (canceled)

11. The resistive random access memory device as claimed in claim 6, wherein the aluminum oxide layer has a thickness of 0.3 nm to 0.6 nm, and the titanium nitride layer has a thickness of 10 nm to 20 nm.

12. The resistive random access memory device as claimed in claim 1, wherein the oxidizable layer contains oxygen migrating from the resistive switching layer, the oxygen further migrating from the oxidizable layer to the resistive switching layer tends to accumulate at a first interface between the oxidizable layer and the first oxygen diffusion barrier layer, and the oxygen migrating from the oxidizable layer to the top electrode tends to accumulate at a second interface between the oxidizable layer and the second oxygen diffusion barrier layer.
